(19) United States
(12) Patent Application Publication
(10) Pub. No.: US 2025/0174574 A1
(43) Pub. Date: May 29, 2025

(54) CHIP PACKAGE WITH ELECTRICAL SHIELDING STRUCTURE AND MESH PAD STRUCTURE

(71) Applicant: XINTEC INC., Taoyuan City (TW)

(72) Inventors: Wei-Ming CHIEN, Taoyuan City (TW); Po-Han LEE, Taipei City (TW); Yi-Jui HOU, Taichung City (TW)

(21) Appl. No.: 18/940,867

(22) Filed: Nov. 8, 2024

Related U.S. Application Data
(60) Provisional application No. 63/603,585, filed on Nov. 28, 2023.

(51) Int. Cl. H01L 23/552; H01L 27/146

(52) U.S. Cl. CPC H01L 23/552; H10F 39/811

(57) ABSTRACT

Chip packages are provided. The chip package includes a device substrate, at least one signal/power pad, and a patterned metal plate. The device substrate has an active surface and a backside surface. The device substrate includes a first opening and a second opening that extend from the backside surface through the device substrate to the active surface. The signal/power pad is disposed on the backside surface of the device substrate. The patterned metal plate is disposed on the backside surface, and it surrounds and is separated from the signal/power pad. The patterned metal plate includes a plurality of first slit openings exposing the backside surface, extending along a first direction and arranged parallel to each other.

### CROSS REFERENCE TO RELATED APPLICATIONS

This application claims the benefit of U.S. Provisional Application No. 63/603,585, filed Nov. 28, 2023, the entirety of which is incorporated by reference herein.

### BACKGROUND OF THE INVENTION

### Field of the Invention

The invention relates in general to a packaging technology, and in particular it relates to a chip package having an electrical shielding structure and a mesh pad structure.

### Description of the Related Art

Optoelectronic devices (e.g., image sensing devices) are widely used in electronic products such as digital cameras, digital video recorders mobile phones, and the like. The chip package process is an important step in the fabrication of electronic products. Chip packages not only protect sensing chips from outside environmental contaminants, but they also provide electrical connection paths allowing the electronic elements inside the sensing chip to be connected to exterior circuits.

Many challenges have arisen as the chip package manufacturing process has become more complex. For example, electromagnetic interference (EMI) often reduces or affects the performance of electronic devices or circuits within chip packages. In general, a grounding plate or an additional electrically shielded plate are employed to prevent electromagnetic interference during operation. However, chip package manufacturing still faces challenges with ground plates and other electrical shielding plates.

### BRIEF SUMMARY OF THE INVENTION

An embodiment of the present disclosure provides an electrical shielding structure. The electrical shielding structure includes a substrate and a patterned metal plate. At least one signal/power pad is disposed on the surface of the substrate. The patterned metal plate is disposed on the surface of the substrate, surrounding and separated from the signal/power pad. Moreover, the patterned metal plate includes a plurality of slit openings that expose the surface of the substrate, extend along a first direction, and are arranged parallel to each other.

An embodiment of the present disclosure provides an electrical shielding structure. The electrical shielding structure includes a substrate and a patterned metal plate. At least one signal/power pad is disposed on the surface of the substrate. The patterned metal plate is disposed on the surface of the substrate, surrounding and separated from the signal/power pad. Moreover, the patterned metal plate includes a plurality of first slit openings and a plurality of second slit openings. The first slit openings expose the surface of the substrate, extend along a first direction, and are arranged parallel to each other. The second slit openings expose the surface of the substrate. The second slit openings extend in a second direction and are arranged parallel to each other. The second direction is different from the first direction.

Another embodiment of the present disclosure provides a chip package. The chip package includes a device substrate, at least one signal/power pad, and a patterned metal plate. The device substrate has an active surface and a backside surface. The device substrate includes a first opening and a second opening that extend from the backside surface through the device substrate to the active surface. The signal/power pad is disposed on the backside surface of the device substrate. The patterned metal plate is disposed on the backside surface, surrounds and is separated from the signal/power pad. The patterned metal plate includes a plurality of first slit openings exposing the backside surface, extending along a first direction and arranged parallel to each other.

Another embodiment of the present disclosure provides a chip package. The chip package includes a device substrate having an active surface and a backside surface. The device substrate includes an opening that extends from the backside surface through the device substrate to the active surface. The chip package also includes an insulating layer disposed on the device substrate and having an upper surface defined by the active surface of the device substrate. The chip package further includes a first metal layer and a second metal layer in the insulating layer. The first metal layer has a plurality of first through-holes arranged in a first array. The second metal layer is stacked over the first metal layer and has a plurality of second through-holes arranged in a second array. The second array is transversely shifted with respect to the first array, as viewed from a top-view perspective, so that the second through-holes do not overlap the first through-holes.

Another embodiment of the present disclosure provides a chip package. The chip package includes a device substrate having an active surface and a backside surface. The device substrate includes an opening that extends from the backside surface through the device substrate to the active surface. The chip package also includes an insulating layer disposed on the device substrate and having an upper surface defined by the active surface of the device substrate, a spacer layer disposed over the insulating layer, and a cover plate capping the spacer layer to form a cavity between the device substrate and the cover plate and surrounded by the spacer layer. The opening is directly below the cavity, so that inner sidewalls of the spacer layer are laterally spaced apart from the opening, as viewed from a top-view perspective.

### BRIEF DESCRIPTION OF THE DRAWINGS

The present disclosure can be more fully understood by reading the subsequent detailed description and examples with references made to the accompanying drawings, wherein:

FIG. 1 is a cross-sectional view of an exemplary chip package according to some embodiments.

FIG. 2 is a plan view of an exemplary electrical shielding structure according to some embodiments.

FIG. 3 is a plan view of an exemplary electrical shielding structure according to some embodiments.

FIG. 4A is a cross-sectional view of an exemplary chip package according to some embodiments.

FIG. 4B is a cross-sectional view of an exemplary chip package according to some embodiments.

FIG. 5A is a plan view of an exemplary first metal layer of a multi-layer conductive pad structure in the chip package shown in FIG. 4B according to some embodiments.

FIG. 5B is a plan view of an exemplary second metal layer of the multi-layer conductive pad structure in the chip package shown in FIG. 4B according to some embodiments.

FIG. 5C-1 is a plan view of an exemplary third metal layer of the multi-layer conductive pad structure in the chip package shown in FIG. 4B according to some embodiments.

FIG. 5C-2 is a plan view of an exemplary third metal layer of the multi-layer conductive pad structure shown in FIG. 5A according to some embodiments.

FIG. 6 is an enlarged cross-sectional view of the region PS1 shown in FIG. 4B according to some embodiments.

FIG. 7 is an enlarged cross-sectional view of the region PS1 shown in FIG. 4B according to some embodiments.

FIG. 8 is an enlarged cross-sectional view of the region PS1 shown in FIG. 4B according to some embodiments.

FIG. 9 is an enlarged cross-sectional view of the region PS1 shown in FIG. 4B according to some embodiments.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed. Moreover, when a first material layer is referred to as being on or overlying a second material layer, the first material layer may be in direct contact with the second material layer, or separated from the second material layer by one or more material layers.

A chip package according to some embodiments of the present disclosure may be used to package micro-electro-mechanical system chips. However, embodiments of the invention are not limited thereto. For example, the chip package of the embodiments of the invention may be implemented to package active or passive devices or electronic components of integrated circuits, such as digital or analog circuits. For example, the chip package is related to optoelectronic devices, micro-electro-mechanical systems (MEMS), biometric devices, micro fluidic systems, and physical sensors measuring changes to physical quantities such as heat, light, capacitance, pressure, and so on. In particular, a wafer-level package (WSP) process may optionally be used to package semiconductor chips, such as image-sensor elements, light-emitting diodes (LEDs), solar cells, RF circuits, accelerators, gyroscopes, fingerprint recognition devices, micro actuators, surface acoustic wave devices, pressure sensors, ink printer heads, and so on.

The above-mentioned wafer-level package process mainly means that after the packaging step is accomplished during the wafer stage, the wafer with chips is cut to obtain individual packages. However, in a specific embodiment, separated semiconductor chips may be redistributed on a carrier wafer and then packaged, which may also be referred to as a wafer-level package process. In addition, the above-mentioned wafer-level package process may also be adapted to form a chip package having multi-layer integrated circuit devices by a stack of a plurality of wafers having integrated circuits.

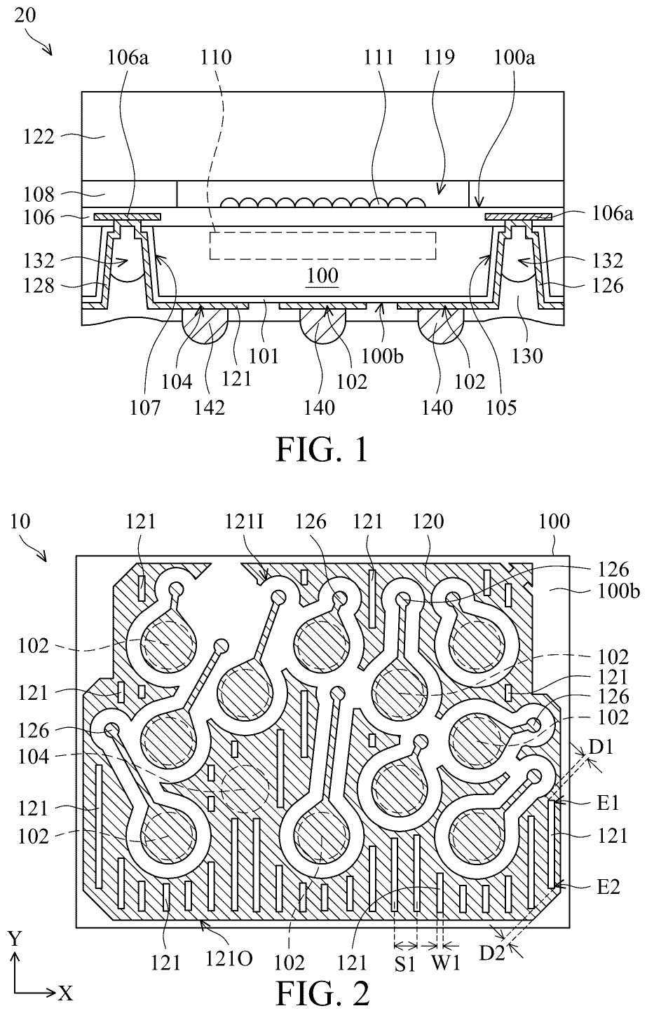

Referring to FIG. 1, which illustrates a cross-sectional view of an exemplary chip package 20 according to some embodiments. In some embodiments, the chip package 20 is implemented with a front side illumination (FSI) sensing device and includes a semiconductor substrate 100. The semiconductor substrate 100 has an upper surface 100a (e.g., active surface) and a lower surface 100b (e.g., backside surface) opposite to the upper surface 100a. The semiconductor substrate 100 may be made of silicon or other semiconductors.

In some embodiments, the semiconductor substrate 100 includes a sensing region 110. Moreover, the sensing region 110 includes a sensing device (not shown) adjacent to the lower surface 100b of the semiconductor substrate 100. For example, the sensing region 110 may include an image sensing device or another suitable sensing device. In some other embodiments, the sensing region 110 includes a device for sensing biometric identification (e.g., a fingerprint recognition device), a device for sensing environmental characteristics (e.g., a temperature sensing device, a humidity sensing device, a pressure sensing device, or capacitive sensing device) or another suitable sensing device. Therefore, semiconductor substrate 100 is also referred to herein as a device substrate.

In some embodiments, an insulating layer 106 is disposed on a first side of the semiconductor substrate 100, and the surface of the insulating layer 106 constitutes the upper surface 100a (i.e., the active surface) of the semiconductor substrate 100. In some embodiments, the insulating layer 106 includes an interlayer dielectric (ILD) layer, an inter-metal dielectric (IMD) layer, a passivation layer, or a combination thereof. In some embodiments, the insulating layer 106 includes an inorganic material such as silicon oxide, silicon nitride, silicon oxynitride, metal oxide, or combinations thereof or another suitable insulating material.

In some embodiments, the insulating layer 106 includes one or more conductive pads 106a disposed therein and adjacent to the upper surface 100a of the semiconductor substrate 100. In one embodiment, the conductive pad 106a may be a single conductive layer or a multi-layer conductive structure. To simplify the diagram, only some single conductive layers 106a are shown here as examples. In some embodiments, the insulating layer 106 includes openings exposing corresponding conductive pads 106a. In one embodiment, the sensing device in the sensing region 110 can be electrically connected to the conductive pad 106a through the interconnect structure (not shown) in the semiconductor substrate 100 and the insulating layer 106.

In some embodiments, there are openings extending from the lower surface 100b of the semiconductor substrate 100 through the semiconductor substrate 100 to the upper surface 100a of the semiconductor substrate 100. Moreover, these openings expose the corresponding conductive pads 106a in the insulating layer 106. To simplify the illustration, only a first opening 105 and a second opening 107 are depicted herein. Moreover, the first opening 105 and the second opening 107 have tapered sidewalls. For example, the first diameter (i.e., the bottom width) of the first opening 105 and that of the second opening 107 at the lower surface 100b of the semiconductor substrate 100 are larger than the second diameter (i.e., the top width) of the first opening 105 and that of the second opening 107 at the upper surface 100a of the semiconductor substrate 100.

In some embodiments, the chip package 20 further includes an insulating liner layer 101 covering a second side (opposite to the first side) of the semiconductor substrate 100, and the surface of the insulating liner layer 101 constitutes the lower surface 100b (i.e., backside surface) of the semiconductor substrate 100. Moreover, the insulating liner layer 101 conformally extends to the sidewalls and the bottom of the first opening 105 and these of the second opening 107. The insulating liner layer 101 formed in the first opening 105 and the second opening 107 has openings to expose the corresponding conductive pads 106a. In some embodiments, the insulating liner layer 101 may include epoxy resin, inorganic materials (e.g., silicon oxide, silicon nitride, silicon oxynitride, metal oxides, or combinations thereof), organic polymer materials (e.g., polyimide, butylcyclobutene (BCB), parylene, polynaphthalenes, fluorocarbons, acrylates) or other suitable insulating materials.

In some embodiments, the chip package 20 further includes a patterned metal layer disposed on the insulating liner layer 101 on the lower surface 100b of the semiconductor substrate 100, so that the insulating liner layer 101 is formed between the patterned metal layer and semiconductor substrates 100. In some embodiments, the patterned metal layer includes signal/power pads 102 and a patterned metal plate 120 (also called a ground plate) on the lower surface 100b of the semiconductor substrate 100. The patterned metal plate 120 surrounds and is separated from the signal/power pads 102 without contacting them. The signal/power pads 102 and the patterned metal plate 120 are electrically isolated from the surface of the semiconductor substrate 100 via the insulating liner layer 101. In some embodiments, the patterned metal plate 120 (i.e., the ground plate) serves as an electrical shielding plate to prevent electromagnetic interference (EMI) during operation of the chip package 20.

In some embodiments, the patterned metal layer further includes redistribution layers. The redistribution layers are electrically connected to the patterned metal plate 120 and the signal/power pads 102, respectively. Moreover, the redistribution layers are correspondingly disposed in the openings of the semiconductor substrate 100 (such as the first opening 105 and the second opening 107). For example, a first redistribution layer 126 is correspondingly disposed in the first opening 105 and extends to one or more corresponding signal/power pads 102 to be electrically connected thereto. Similarly, a second redistribution layer 128 is correspondingly disposed in the second opening 107 and extends to ground pad region 104 of the patterned metal plate 120 to be electrically connected thereto.

In some embodiments, the first redistribution layer 126 and the second redistribution layer 128 extend to the insulating liner layer 101 on the lower surface 100b of the semiconductor substrate 100, so that the insulating liner layer 101 is formed between the first and second redistribution layers 126 and 128 and the semiconductor substrate 100. Moreover, the first redistribution layer 126 and the second redistribution layer 128 conformally extend to the sidewalls and bottoms of the corresponding openings (for example, the first opening 105 and the second opening 107) and are directly or indirectly electrically connected to the exposed and corresponding conductive pads 106a. Therefore, the first redistribution layer 126 and the second redistribution layer 128 in the first opening 105 and the second opening 107 are also called through-substrate vias (TSVs). In some embodiments, each of the first redistribution layer 126 and the second redistribution layer 128 includes aluminum, titanium, tungsten, copper, or a combination thereof.

In some embodiments, the chip package 20 further includes a passivation layer 130 disposed on the lower surface 100b of the device substrate 100, and partially fills the first opening 105 and the second opening 107, so as to cover the redistribution layer 126 and the second redistribution layer 128. In some embodiments, the passivation layer 130 has an uneven surface. For example, the surface of the passivation layer 130 has recessed portions corresponding to the first opening 105 and the second opening 107. In one embodiment, the passivation layer 130 may include epoxy resin, solder mask, inorganic materials (for example, silicon oxide, silicon nitride, silicon oxynitride, metal oxide or a combination thereof), organic polymer materials (e.g., polyimide, butylcyclobutene (BCB), parylene, polynaphthalenes, fluorocarbons, acrylates) or other suitable insulating materials.

Since the passivation layer 130 does not entirely fill the second opening 107, a hole 132 is formed between the first redistribution layer 126 and the passivation layer 130 in the first opening 105, and another hole 132 is formed between the second redistribution layer 128 and the passivation layer 130 in the second opening 107. Therefore, when the heat treatment is performed in the subsequent process, the holes 132 can serve as buffers between the passivation layer 130 and the first redistribution layer 126 and between the passivation layer 130 and the second redistribution layer 128, thereby reducing undesired stress as a result of mismatch of thermal expansion coefficients between the passivation layer 130 and the first redistribution layer 126 and between the passivation layer 130 and the second redistribution layer 128. In one embodiment, the interface between the hole 132 and the passivation layer 130 has an arcuate contour.

The passivation layer 130 formed on the lower surface 100b of the device substrate 100 has openings to expose the signal/power pads 102 and the ground pad region 104. Moreover, conductive connectors (e.g., solder balls, bumps or conductive pillars) are electrically connected to the exposed signal/power pads 102 and the ground pad region 104 through the openings of the passivation layer 130. For example, a first conductive connector 140 (also called a signal/power connector) is disposed on the surface of the corresponding signal/power pad 102 and is electrically connected thereto, and a second conductive connector 142 (also called a ground connector) is disposed on the surface of the patterned metal plate 120 and is electrically connected thereto. In some embodiments, the first conductive connector 140 and the second conductive connector 142 may include tin, lead, copper, gold, nickel, or a combination thereof.

In some embodiments, the chip package 20 further includes an optical component 111 disposed on the insulating layer 106 and corresponding to the sensing region 102. In one embodiment, the optical component 111 includes a microlens array, a filter layer, a combination thereof, or another suitable optical component.

In some embodiments, the chip package 20 further includes a cover plate 122 disposed on the upper surface 100a of the device substrate 100 to protect the optical component 111. The cover plate 122 may include glass, quartz, transparent polymer material, or another suitable transparent material. Moreover, a spacer layer (or dam) 108 is disposed between the device substrate 100 and the cover plate 122. The spacer layer 108 covers the conductive pads 106a and exposes the optical component 111. In some embodiments, the cover plate 122, the spacer layer 108 and the insulating layer 106 together enclose a cavity 119 above the sensing region 110, so that the optical component 111 is located in the cavity 119. In other embodiments, the spacer layer 108 covers the optical component 111 so that there is no cavity between the cover plate 122 and the insulating layer 106.

In some embodiments, the spacer layer 108 may include epoxy resin, inorganic materials (e.g., silicon oxide, silicon nitride, silicon oxynitride, metal oxides or combinations thereof), organic polymer materials (e.g., polyimide, butylcyclobutene (BCB), parylene, polynaphthalenes, fluorocarbons, acrylates), photoresist material or another suitable insulating material.

Referring to FIG. 2, which illustrates a plan view of an exemplary electrical shielding structure 10 according to some embodiments. In some embodiments, the electrical shielding structure 10 can be used in the chip package 20 of FIG. 1. In this case, the electrical shielding structure 10 includes a device substrate 100 and a patterned metal plate 120. One or more signal/power pads 102 and the patterned metal plate 120 are disposed on one surface of the device substrate 100 (e.g., lower surface 100b (i.e., backside surface)).

In some embodiments, each of the signal/power pads 102 is connected to a redistribution layer (e.g., the first redistribution layer 126). Moreover, the patterned metal plate 120 surrounds and is separated from the signal/power pad 102 and the first redistribution layer 126 that is connected to the signal/power pad 102. In other words, there is no physical contact between the inner edge 1211 (or inner sidewall) of the patterned metal plate 120 and the signal/power pads 102 having the first redistribution layer 126 connected thereto.

In some embodiments, the patterned metal plate 120 includes first slit openings 121 extending along a first direction (e.g., Y direction) and arranged parallel to each other. Each of the first slit openings 121 exposes the lower surface 100b of the device substrate 100. However, in other embodiments, the first slit openings 121 extend along a second direction (e.g., X direction) different from the first direction and are arranged parallel to each other. For example, the first slit openings 121 may be elongated rectangular openings arranged parallel to each other, as viewed from a top-view perspective, and may be dispersedly formed throughout the patterned metal plate 120. Moreover, the width W1 of each of the first slit openings 121 is in a range of about 20 microns to about 40 microns (e.g., 30 microns). In addition, at least two of the first slit openings 121 have the same or different lengths from each other.

In some embodiments, each of the first slit openings 121 is formed between the outer edge 1210 and the inner edge 1211 of the patterned metal plate 120, but does not extend to the outer edge 1210 and/or the inner edge 1211. For example, at least one of the first slit openings 121 has an end portion E1 adjacent to the inner edge 1211 of the patterned metal plate 120, and the minimum distance D1 between the end portion E1 and the inner edge 1211 is in a range of about 20 microns to about 40 microns (e.g., 30 microns). Moreover, at least one of the first slit openings 121 has an end portion adjacent to the outer edge 1210 of the patterned metal plate 120, and the minimum distance D2 between the end portion and the outer edge 1210 is in a range of about 20 microns to about 40 microns (e.g., 30 microns). In some embodiments, the distance S1 between two adjacent slit openings of the first slit openings 121 is in a range of about 80 microns to about 120 microns (e.g., 100 microns).

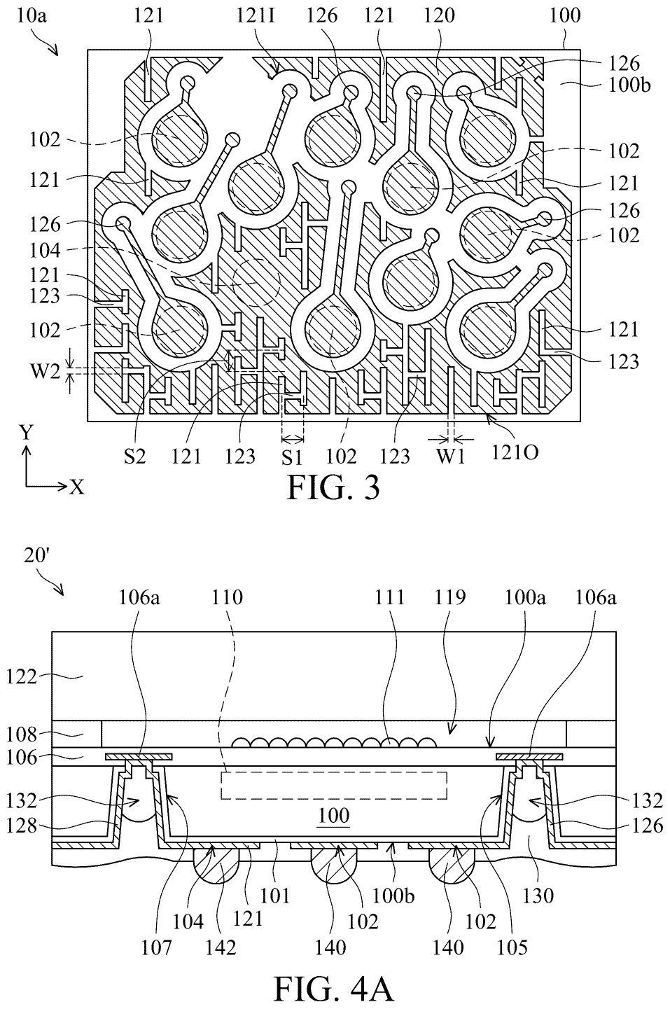

Referring to FIG. 3, which illustrates a plan view of an exemplary electrical shielding structure 10a according to some embodiments. Elements in FIG. 3 that are the same as those in FIG. 2 are labeled with the same reference numbers as in FIG. 2 and in the interests of brevity, they are not described again. The structure of the electrical shielding structure 10a is similar to the electrical shielding structure 10 shown in FIG. 2. However, unlike the electrical shielding structure 10, in addition to the first slit openings 121 extending along the first direction (e.g., Y direction) and arranged parallel to each other in the patterned metal plate 120 in the electrical shielding structure 10 a, the electrical shielding structure 10a also includes second slit openings 123 extending along the second direction (e.g., X direction) and arranged parallel to each other.

Similar to the first slit openings 121, these second slit openings 123 may be elongated rectangular openings arranged parallel to each other, as viewed from a top-view perspective, and may be dispersedly formed throughout the patterned metal plate 120. In some embodiments, at least one second slit opening 123 extends to one first slit opening 121 to form a T-shaped or L-shaped slit opening, as viewed from a top-view perspective. Moreover, at least one second slit opening 123 extends between and contacts two adjacent first slit openings 121 to form an H-shaped or I-shaped slit opening, as viewed from a top-view perspective.

Similar to the first slit openings 121, the width W2 of each of these second slit openings 123 is the range from about 20 microns to about 40 microns (e.g., 30 microns). In addition, at least two of the second slit openings 123 have the same or different lengths from each other. Moreover, in some embodiments, the space S1 between two adjacent slit openings 121 is in a range of about 80 microns to about 120 microns (e.g., 100 microns), and the space S2 between two adjacent second slit openings 123 is in a range of about 80 microns to about 120 microns (e.g., 100 microns).

Different from the electrical shielding structure 10, in the electrical shielding structure 10a, at least one first slit opening 121 and at least one second slit opening 123 extend to the outer edge 1210 and/or the inner edge 1211.

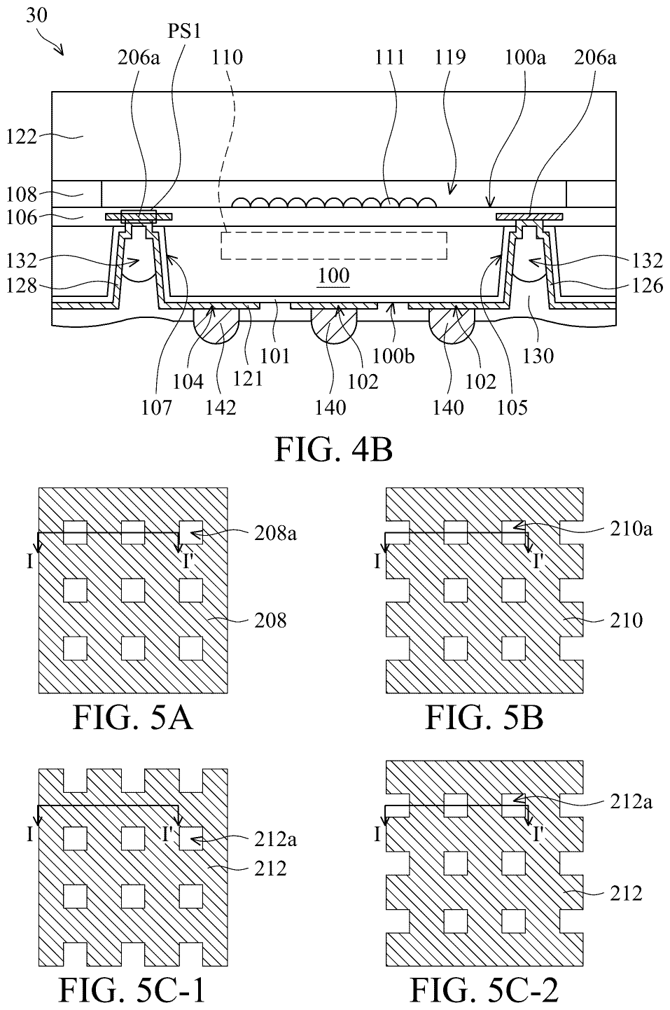

Referring to FIG. 4A, which illustrates a cross-sectional view of an exemplary chip package 20′ according to some embodiments. Elements in FIG. 4A that are the same as those in FIG. 1 are labeled with the same reference numbers as in FIG. 1 and in the interests of brevity, they are not described again. The structure of the chip package 20′ is similar to the chip package 20 shown in FIG. 1. However, unlike the chip package 20, the first and second openings 105 and 107 formed in the semiconductor substrate 100 and the conductive pads 106a disposed in the insulating layer 106 are not directly below the spacer layer 108. In some embodiments, as viewed from a top-view perspective, the first and second openings 105 and 107 and the corresponding conductive pads 106a are directly below the cavity 119, so that the inner sidewalls of the spacer layer 108 are laterally spaced apart from the first and second openings 105 and 107, as shown in FIG. 4A. In those cases, the insulating layer 106 has sufficient thickness to serve as a supporting layer during the formation of the first and second openings 105 and 107, thereby preventing the insulating layer 106 and the conductive pads 106a from becoming damaged or cracked. For example, the insulating layer 106 has a thickness of about 9 μm or more.

Since the first and second openings 105 and 107 are not formed below the spacer layer 108, the width of the spacer layer 108 is not limited by the locations of the first and second openings 105 and 107. In other words, the width of the spacer layer 108 can be varied or reduced for design demands. Moreover, since the first and second openings 105 and 107 are formed below the cavity 119, the design flexibility for the locations of through-substrate vias (which are formed in the first and second openings 105 and 107) can be increased.

Referring to FIG. 4B, which illustrates a cross-sectional view of an exemplary chip package 30 according to some embodiments. Elements in FIG. 4B that are the same as those in FIG. 4A are labeled with the same reference numbers as in FIG. 4A and in the interests of brevity, they are not described again. The structure of the chip package 30 is similar to the chip package 20′ shown in FIG. 4A. However, unlike the chip package 20′ that includes the solid conductive pads 106a (e.g., a solid metal layer), the chip package 30 includes conductive pad structures. Each of the conductive pad structures is a multi-layer pad structure that includes an insulating layer 106 and a stack 206a of conductive layers (e.g., metal layers) with through-holes formed therein. Therefore, the conductive pad structure may be also referred to as a mesh pad structure. The mesh pad structure helps to release the stress from the stack 206a of conductive layers propagates to the insulating layer 106, so as to prevent the delamination of the stack 206a of conductive layers. In some embodiments, the stack 206a of conductive layers includes two or more stacked conductive layers. Moreover, the through-holes in each conductive layer are arranged in an array. For example, the stack 206a of conductive layers may include a first metal layer 208, a second metal layer 210 arranged over the first metal layer 208, and a third metal layer 212 arranged over the second metal layer 210.

FIG. 5A illustrates a plan view of the first metal layer 208 in the chip package 30 shown in FIG. 4B according to some embodiments. FIG. 5B illustrates a plan view of the second metal layer 210 in the chip package 30 shown in FIG. 4B according to some embodiments. FIG. 5C-1 illustrates a plan view of third metal layer 212 in the chip package 30 shown in FIG. 4B according to some embodiments. FIG. 5C-2 illustrates a plan view of third metal layer 212 in the chip package 30 shown in FIG. 4B according to some embodiments. In some embodiments, the first metal layer 208 has first through-holes 208a arranged in a first array. Similarly, the second metal layer 210 has second through-holes 210a arranged in a second array and the third metal layer 212 has third through-holes 212a arranged in a third array.

In some embodiments, the second array is transversely shifted with respect to the first array, as viewed from a top-view perspective, as shown in FIGS. 5A and 5B. As a result, the second through-holes 210a do not overlap any of the first through-holes 208a, as viewed from a top-view perspective. In some embodiments, unlike the second array, the third array is longitudinally shifted with respect to the first array, as viewed from a top-view perspective, as shown in FIG. 5C-1. As a result, the third through-holes 212a do not overlap the first through-holes 208a and the second through-holes 210a, as viewed from a top-view perspective.

In some other embodiments, the through-hole pattern in the third metal layer 212 is the same as that in the second metal layer 210, as shown in FIG. 5C-2. In other words, the third array overlaps the second array, as viewed from a top-view perspective. As a result, the third through-holes 212a overlap the second through-holes 210a, but do not overlap the first through-holes 208a, as viewed from a top-view perspective.

The first through-holes 208a, the second through-holes 210a, and the third through-holes 212a have a square shape, as viewed from a top-view perspective, as shown in FIGS. 5A, 5B, 5C-1, and 5C-2. However, the first and second through-holes 208a and 210a may have other shapes for design demands. For example, those through-holes may have a circular, triangular, rectangular, or polygonal shape. In addition, it is appreciated that the numbers of the first, second, and third through-holes 208a, 210a, and 212a can be varied and are not limited to the embodiments shown in FIGS. 5A, 5B, 5C-1, and 5C-2.

FIG. 6 is an enlarged cross-sectional view of a region PS1 shown in FIG. 4B according to some embodiments, which also illustrates a cross-sectional view of a stack structure of the first, second, and third metal layers 208, 210, and 212 taken along line I-I′ shown in FIGS. 5A, 5B, and 5C-1. The region PS1 shows a conductive pad structure including an insulating layer 106 and a stack 206a of conductive layers therein, and the second redistribution layer 104 is electrically connected to the stack 206a of conductive layers. Each of the stack 206a of conductive layers formed in the insulating layer 106 corresponds to the opening (e.g., the first opening 105 or the second opening 107) in the device substrate 100. Moreover, the redistribution layer (e.g., the first redistribution layer 102 or the second redistribution layer 104) is electrically connected to the corresponding stack 206a of conductive layers via the corresponding opening in the device substrate 100.

For example, in the region PS1, the stack 206a of conductive layers corresponds to the second opening 107 (as shown in FIG. 4B) and includes first, second, and third metal layers 208, 210, and 212 (as shown in FIGS. 5A, 5B, and 5C-1) that are successively stacked from bottom to top. Moreover, the first metal layer 208 is electrically connected to the second metal layer 210 through conductive vias V1 formed in the insulating layer 106 between the first metal layer 208 and the second metal layer 210. Similarly, the second metal layer 210 is electrically connected to the third metal layer 212 through conductive vias V2 formed in the insulating layer 106 between the second metal layer 210 and the third metal layer 212.

The first metal layer 208 having the through-holes 208a is exposed from the second opening 107 (not shown in FIG. 6). Moreover, the second redistribution layer 104 is disposed in the second opening 107 and extends into the insulating layer 106, so as to be in direct contact with the first metal layer 208 and portions of the insulating layer 106 filled in the first through-holes 208a.

Similarly, another stack 206a of conductive layers corresponds to the first opening 105 (as shown in FIG. 4B), where the first metal layer 208 having the through-holes 208a is exposed from the first opening 105. The first redistribution layer 102 is disposed in the first opening 105 and extends into the insulating layer 106, so as to be in direct contact with the corresponding first metal layer 208 and portions of the insulating layer 106 filled in the corresponding first through-holes 208a.

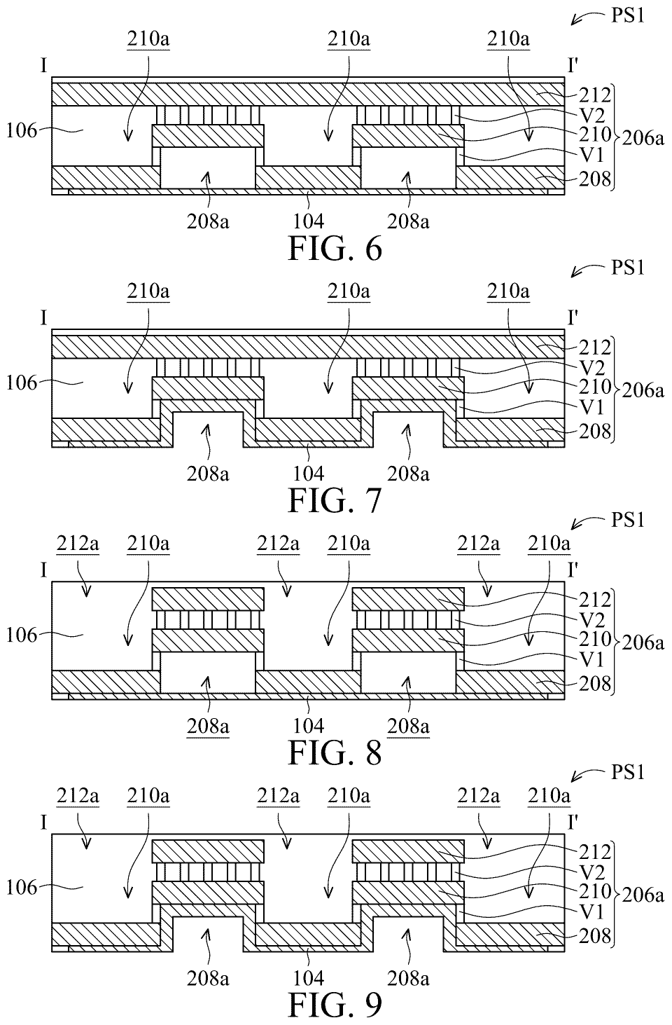

FIG. 7 is an enlarged cross-sectional view of a region PS1 shown in FIG. 4B according to some embodiments, which also illustrates a cross-sectional view of a stack structure of the first, second, and third metal layers 208, 210, and 212 taken along line I-I′ shown in FIGS. 5A, 5B, and 5C-1. The region PS1 shows a conductive pad structure including an insulating layer 106 and a stack 206a of conductive layers therein, and the second redistribution layer 104 is electrically connected to the stack 206a of conductive layers. The structure in the region PS1 shown in FIG. 7 is similar to the structure in the region PS1 shown in FIG. 6. Unlike the structure in the region PS1 shown in FIG. 6, the second redistribution layer 104 extends into the insulating layer 106, so as to be in direct contact with the first metal layer 208 and fill the first through-holes 208a to be in direct contact with the second metal layer 210. In those cases, the insulating layer 106 covering the first metal layer 208 and filled in the first through-holes 208a may be fully removed after the formation of the second opening 107 by one or more etching processes. As a result, the process window for the formation of the second opening 107 can be increased, thereby ensuring that the subsequently formed first redistribution layer 102 is in direct contact with the first metal layer 208.

Similarly, another stack 206a of conductive layers corresponds to the first opening 105 (as shown in FIG. 4B), where the first metal layer 208 having the through-holes 208a is exposed from the first opening 105. The first redistribution layer 102 is disposed in the first opening 105 and extends into the insulating layer 106, so as to be in direct contact with the corresponding first metal layer 208 and fill the corresponding first through-holes 208a to be in direct contact with the corresponding second metal layer 210.

FIG. 8 is an enlarged cross-sectional view of a region PS1 shown in FIG. 4B according to some embodiments, which also illustrates a cross-sectional view of a stack structure of the first, second, and third metal layers 208, 210, and 212 taken along line I-I′ shown in FIGS. 5A, 5B, and 5C-2. The region PS1 shows a conductive pad structure including an insulating layer 106 and a stack 206a of conductive layers therein, and the second redistribution layer 104 is electrically connected to the stack 206a of conductive layers. The structure in the region PS1 shown in FIG. 8 is similar to the structure in the region PS1 shown in FIG. 6. Unlike the structure in the region PS1 shown in FIG. 6, the through-hole pattern in the third metal layer 212 is the same as that in the second metal layer 210. As a result, the third array overlaps the second array, as viewed from a top-view perspective, so that the third through-holes 212a overlap the second through-holes 210a, but do not overlap the first through-holes 208a, as viewed from a top-view perspective. FIG. 9 is an enlarged cross-sectional view of a region PS1 shown in FIG. 4B according to some embodiments, which also illustrates a cross-sectional view of a stack structure of the first, second, and third metal layers 208, 210, and 212 taken along line I-I′ shown in FIGS. 5A, 5B, and 5C-2. The region PS1 shows a conductive pad structure including an insulating layer 106 and a stack 206a of conductive layers therein, and the second redistribution layer 104 is electrically connected to the stack 206a of conductive layers. The structure in the region PS1 shown in FIG. 8 is similar to the structure in the region PS1 shown in FIG. 7. Unlike the structure in the region PS1 shown in FIG. 7, the through-hole pattern in the third metal layer 212 is the same as that in the second metal layer 210. As a result, the third array overlaps the second array, as viewed from a top-view perspective, so that the third through-holes 212a overlap the second through-holes 210a, but do not overlap the first through-holes 208a, as viewed from a top-view perspective.

According to the above embodiments, the large-area patterned metal plate in the electrical shielding structure has slit openings formed therein and arranged in parallel along a single direction, or has slit openings arranged in parallel along the first direction and slit openings arranged in parallel along the second direction. Through the above-mentioned slit openings, the stress between the large-area patterned metal plate and the device substrate can be reduced, thereby preventing the patterned metal plate from being delaminated from the lower surface of the device substrate. As a result, the reliability of the electrical shielding structure within the chip package can be increased, thereby effectively preventing electromagnetic interference during operation of the chip package. According to the above embodiments, the conductive pad with a single layer or the conductive pad structure including a multi-layer pad structure corresponding to the opening for formation of TSV is directly below the cavity defined by cover plate and a spacing layer that are formed over the device substrate. As a result, the width of the spacer layer can be varied or reduced for design demands. Moreover, the design flexibility for the locations of TSVs can be increased. According to the above embodiments, the chip package includes a multi-layer pad structure with through-holes. As a result, the mesh pad structure helps to release the stress from the multi-layer pad structure propagates to the adjacent insulating layer, thereby preventing delamination of the multi-layer pad structure. Moreover, the conductive pad structure with through-holes can assist in the full removal of the insulating layer that covers the first metal layer and fill the through-holes in the first metal layer. As a result, the subsequently formed redistribution layer can be in direct contact with the first and second metal layers, so as to increase the contact area between the redistribution layer and the conductive pad structure. Moreover, the process window for the formation of the opening exposing the conductive pad structure can be increased.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip package, comprising:
a device substrate having an active surface and a backside surface, wherein the device substrate comprises a first opening and a second opening that extend from the backside surface through the device substrate to the active surface;
at least one signal/power pad disposed on the backside surface of the device substrate; and
a patterned metal plate disposed on the backside surface, surrounding and separated from the signal/power pad, wherein the patterned metal plate comprises a plurality of first slit openings exposing the backside surface and extending along a first direction and arranged parallel to each other.

2. The chip package as claimed in claim 1, further comprising:
at least one ground connector disposed on and electrically connected to a surface of the patterned metal plate.

3. The chip package as claimed in claim 1, wherein the patterned metal plate further comprises:
a plurality of second slit openings exposing the backside surface, extending along a second direction that is different from the first direction, and arranged parallel to each other.

4. The chip package as claimed in claim 3, wherein at least one second slit opening in the plurality of second slit openings extends to one first slit opening in the plurality of first slit openings, to form a T-shaped or L-shaped slit opening, as viewed from a top-view perspective.

5. The chip package as claimed in claim 3, wherein at least one second slit opening in the plurality of second slit openings is formed between and extends to two adjacent first slit openings in the plurality of first slit openings, to form an H-shaped or I-shaped slit opening, as viewed from a top-view perspective.

6. The chip package as claimed in claim 1, further comprising:
a spacer layer disposed over the active surface of the device substrate;
a cover plate capping the spacer layer to form a cavity between the device substrate and the cover plate and surrounded by the spacer layer; and
a first redistribution layer and a second redistribution layer respectively disposed in the first opening and the second opening, wherein the first redistribution layer extends from the first opening to the signal/power pad, and the second redistribution layer extends from the second opening to the patterned metal plate.

7. The chip package as claimed in claim 6, wherein the first opening and the second opening are directly below the cavity, so that inner sidewalls of the spacer layer are laterally spaced apart from the first opening and the second opening, as viewed from a top-view perspective.

8. The chip package as claimed in claim 1, further comprising:
a first conductive pad structure and a second conductive pad structure adjacent to the active surface of the device substrate and respectively corresponding to the first opening and the second opening, wherein each of the first conductive pad structure and a second conductive pad structure comprises:
an insulating layer having an upper surface defined by the active surface of the device substrate;
a first metal layer in the insulating layer and having a plurality of first through-holes arranged in a first array; and
a second metal layer in the insulating layer, stacked over the first metal layer, and having a plurality of second through-holes arranged in a second array, wherein the second array is transversely shifted with respect to the first array, as viewed from a top-view perspective, so that the plurality of second through-holes does not overlap the plurality of first through-holes.

9. The chip package as claimed in claim 8, further comprising:
a first redistribution layer and a second redistribution layer respectively disposed in the first opening and the second opening and extending into the insulating layer, so as to be in direct contact with the first metal layer and portions of the insulating layer in the plurality of first through-holes.

10. The chip package as claimed in claim 8, further comprising:
a first redistribution layer and a second redistribution layer respectively disposed in the first opening and the second opening and extending into the insulating layer, so as to be in direct contact with the first metal layer and fill the plurality of first through-holes to be in direct contact with the second metal layer.

11. A chip package, comprising:
a device substrate having an active surface and a backside surface, wherein the device substrate comprises an opening that extends from the backside surface through the device substrate to the active surface;
an insulating layer disposed on the device substrate and having an upper surface defined by the active surface of the device substrate;
a first metal layer in the insulating layer and having a plurality of first through-holes arranged in a first array; and
a second metal layer in the insulating layer, stacked over the first metal layer, and having a plurality of second through-holes arranged in a second array, wherein the second array is transversely shifted with respect to the first array, as viewed from a top-view perspective, so that the plurality of second through-holes does not overlap the plurality of first through-holes.

12. The chip package as claimed in claim 11, further comprising:
a redistribution layer disposed in the opening and extending into the insulating layer, so as to be in direct contact with the first metal layer and portions of the insulating layer in the plurality of first through-holes.

13. The chip package as claimed in claim 11, further comprising:
a redistribution layer disposed in the opening and extending into the insulating layer, so as to be in direct contact with the first metal layer and fill the plurality of first through-holes to be in direct contact with the second metal layer.

14. The chip package as claimed in claim 11, further comprising:
a third metal layer in the insulating layer, stacked over the second metal layer, and having a plurality of third through-holes arranged in a third array.

15. The chip package as claimed in claim 14, wherein the third array overlaps the second array, as viewed from a top-view perspective, so that the plurality of third through-holes overlaps the plurality of second through-holes.

16. The chip package as claimed in claim 14, wherein the third array is longitudinally shifted with respect to the first array, as viewed from a top-view perspective, so that the plurality of third through-holes does not overlap the plurality of first through-holes and the plurality of second through-holes.

17. The chip package as claimed in claim 11, further comprising:
a spacer layer disposed over the insulating layer; and
a cover plate capping the spacer layer to form a cavity between the device substrate and the cover plate and surrounded by the spacer layer,
wherein the opening is directly below the cavity, so that the inner sidewalls of the spacer layer are laterally spaced apart from the opening, as viewed from a top-view perspective.

18. A chip package, comprising:
a device substrate having an active surface and a backside surface, wherein the device substrate comprises an opening that extends from the backside surface through the device substrate to the active surface;
an insulating layer disposed on the device substrate and having an upper surface defined by the active surface of the device substrate;
a spacer layer disposed over the insulating layer; and
a cover plate capping the spacer layer to form a cavity between the device substrate and the cover plate and surrounded by the spacer layer,
wherein the opening is directly below the cavity, so that the inner sidewalls of the spacer layer are laterally spaced apart from the opening, as viewed from a top-view perspective.

19. The chip package as claimed in claim 17, further comprising:
a metal pad in the insulating layer and having a plurality of first through-holes arranged in a first array, wherein the opening is extended into the insulating layer to expose the metal pad; and
a redistribution layer disposed in the opening and extending into the insulating layer, so as to be in direct contact with the first metal layer.

20. The chip package as claimed in claim 19, further comprising:
a metal layer in the insulating layer over the metal pad and having a plurality of second through-holes arranged in a second array,
wherein the second array is shifted with respect to the first array, as viewed from a top-view perspective, so that the plurality of second through-holes does not overlap the plurality of first through-holes; and
wherein the redistribution layer extends into the plurality of first through-holes, so as to be in direct contact with the metal layer.
